(19) United States
(12) Patent Application Publication
(10) Pub. No.: US 2004/0238836 A1
(43) Pub. Date: Dec. 2, 2004

(54) Flip chip structure for light emitting diode

(75) Inventors: Ming-Te Lin, Taipei Hsien (TW); Ming-Yao Lin, Panchiao City (TW)

Correspondence Address: TROXELL LAW OFFICE PLLC, SUITE 1404, 5205 LEESBURG PIKE, FALLS CHURCH, VA, 22041, US

(73) Assignee: Para Light Electronics Co., Ltd.

(21) Appl. No.: 10/445,939

(22) Filed: May 28, 2003

(51) Int. Cl. H01L 33/00

(52) U.S. Cl. 257/99

(57) ABSTRACT

A flip chip structure for light emitting diode includes a silicon substrate having a surface on which a number of conductors are mounted in an equally spaced manner with an open space formed between adjacent conductors and a number of chips each forming, on the same surface, positive terminal and negative terminal. The chips are mounted to the surface of the substrate in a flip chip fashion with the positive and negative terminals thereof engaging corresponding ones of the conductors of the substrate to form electrical connection therebetween whereby opposite ends of each conductor form positive and negative electrodes for the chips connected thereto. Ends of the conductors that are not engaged by the chips function as external terminals for connection with an external power source. The chips are selected to give off at least one color of light so that a single light emitting diode device selectively emits light of different colors, while possesses features of high voltage and small current and heat generated by the chips being effectively removed.

### FIELD OF THE INVENTION

The present invention generally relates to a flip chip structure for light emitting diode (LED), and in particular to a light emitting diode device capable of selectively giving off light of a single color or lights of different colors and possesses the features of high voltage and small current and heat generated by the device can be effectively removed.

### BACKGROUND OF THE INVENTION

A conventional light emitting diode device comprises a substrate on which a single chip is mounted with the positive and negative terminals of the chip facing upward. The positive and negative terminals of the chip are then wired to external pins of the device. Thereafter, packaging is performed on the device. Since the light emitting diode device comprises only a single chip, the light emitted from the light emitting diode device is not intense and thus does not meet the requirement of high brightness.

To overcome the intensity problem, it has been suggested to mount more than one chip on the substrate with the positive and negative terminals of the chips facing upward and then wired to the external pins of the light emitting diode device. Thereafter, packaging is performed to complete the manufacturing process of the light emitting diode device. The light emitting diode device so manufactured is capable to give off intense light. However, since the dimension of a light emitting diode is small, the chips that are contained in the light emitting diode is correspondingly tiny in size. This arises difficult in manufacturing process of the light emitting diode device. Further, since the great number of chips is lit at the same time when electricity is supplied to the light emitting diode device, a great voltage is required to simultaneously drive the great number of chips, which leads to a great current. This makes it difficult to properly supply power to the light emitting diode device and a power supply that cooperates with the light emitting diode must have complicated and expensive structure. In addition, power consumption is substantially increased, which in turn leads to a great amount of heat generated during the operation of the light emitting diode. Such heat, if not properly removed, may damage the light emitting diode.

### SUMMARY OF THE INVENTION

Therefore, a primary object of the present invention is to provide a light emitting diode device that is capable to selectively give off lights of different colors or light of a single color.

Another object of the present invention is to provide a light emitting diode that is operable with high voltage and small current.

A further object of the present invention is to provide a light emitting diode that is capable of dissipating heat generated thereby.

To achieve the above objects, in accordance with the present invention, there is provided a light emitting diode device comprising a silicon substrate having a surface on which a number of conductors are mounted in an equally spaced manner with an open space formed between adjacent conductors and a number of chips each forming, on the same surface, positive terminal and negative terminal. The chips are mounted to the surface of the substrate in a flip chip fashion with the positive and negative terminals thereof engaging corresponding ones of the conductors of the substrate to form electrical connection therebetween whereby opposite ends of each conductor form positive and negative electrodes for the chips connected thereto. Ends of the conductors that are not engaged by the chips function as external terminals for connection with an external power source. The chips are selected to give off at least one color of light so that a single light emitting diode device selectively emits light of different colors, while possesses features of high voltage and small current and heat generated by the chips being effectively removed.

### BRIEF DESCRIPTION OF THE DRAWINGS

The present invention will be apparent to those skilled in the art by reading the following description of a preferred embodiment thereof, with reference to the attached drawings, in which:

FIG. 1 is a perspective view of a light emitting diode device constructed in accordance with the present invention;

FIG. 2 is an exploded view of the light emitting diode device of the present invention;

FIG. 3 is a cross-sectional view of the light emitting diode device of the present invention; and

FIG. 4 is a perspective view showing the light emitting diode device of the present invention after being packaged with resin or the likes.

### DETAILED DESCRIPTION OF TUE PREFERRED EMBODIMENT

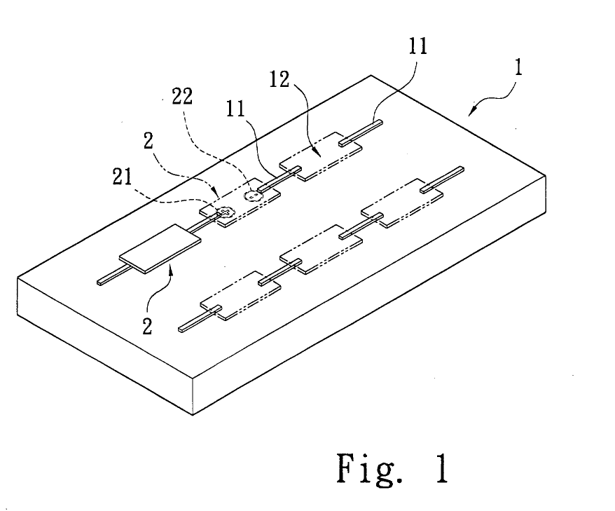

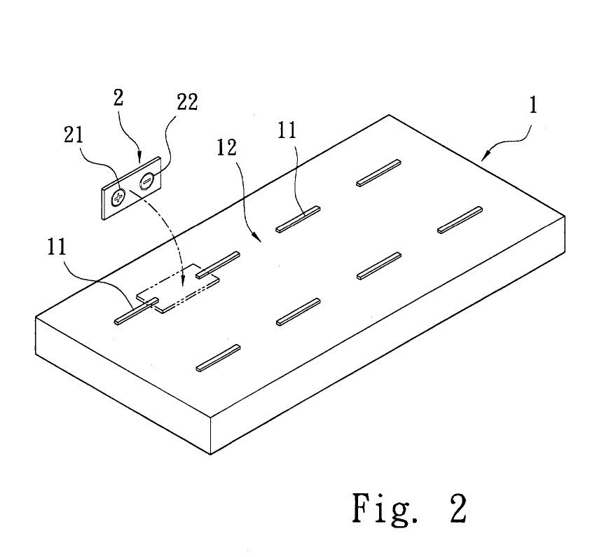

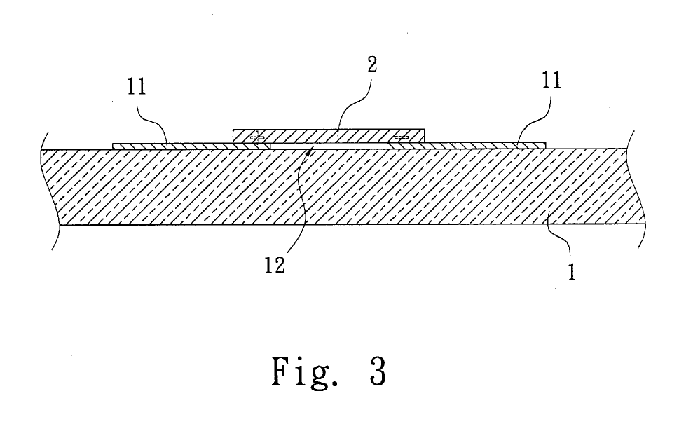

With reference to the drawings and in particular to FIGS. 1-3, a light emitting diode device having a flip chip structure in accordance with the present invention comprises a silicon substrate 1 on which a plurality of chips 2 are mounted in a flip chip manner whereby a single light emitting diode device is capable to provide a single color light source or a multiple color light source. Further, the chips 2 are arranged so that the single light emitting diode unit is operated with a high voltage and small current and is capable to effectively dissipate all the heat generated by the chips 2.

The silicon substrate 1 has a surface on which conductors 11 are mounted in an equally spaced manner. An open space 12 is formed between adjacent conductors 11.

The chips 2 have a positive terminal 21 and a negative terminal 22 on the same surface of the chips 2. The chips 2 are positioned in a flip chip fashion on the substrate 1 so that the positive and negative terminals 21, 22 of the chips 2 physically engage ends of the corresponding conductors 11 on the substrate 1 to form electrical connection therebetween whereby opposite ends of each conductor 11 forms positive and negative electrodes for the corresponding chips 2 that they engage. Ends of the conductors 11 that are not engaged by the terminals 21, 22 of the chips 2 serve as external terminals to which an external power source (not shown) is connected for supply electrical power to the chips 2.

The chips 2 may comprise light emitting elements of the same light color or alternatively, the chips 2 comprise light emitting elements of different light colors. The chips 2 are mounted to the silicon substrate 1 in any combination whereby a single light emitting diode device is capable to give off lights of either the same color or different colors. Thus, a novel flip chip structure for light emitting diode is obtained with the above arrangement.

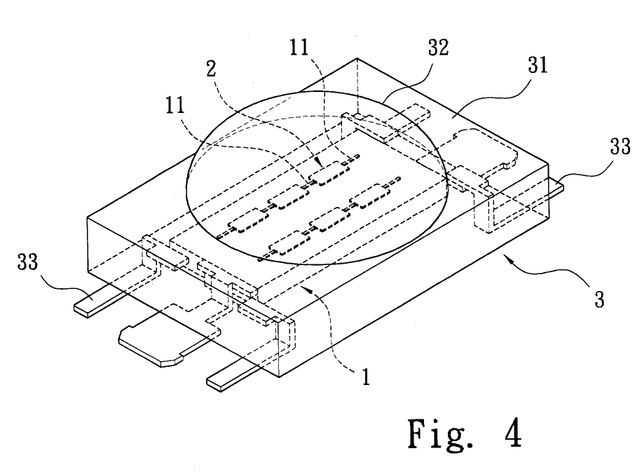

Also referring to FIG. 4, in a practical application, a light emitting diode device 3 formed as described above in accordance with the present invention is packaged with transparent resin packaging material to form a structure comprising a body 31 having a surface on which a convex, light focusing projection 32, preferably dome-shaped, is formed. A number of terminal pins 33 that are electrically connected to the ends of the conductors 11 that are not engaged by the chips 2 extend from opposite sides of the body 31. The terminal pins 33 allow for connection with the external power source (not shown) to supply electricity to the chips 2 via the conductors 11 for generation of single color light or multiple color light. Thus, a single light emitting diode device capable of giving off light of different colors is obtained. Further, the light emitting diode unit possesses the features of high voltage and small current and is capable to dissipate of all the heat generated by the chips 2.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A flip chip structure for light emitting diode comprising:
a silicon substrate having a surface on which a number of conductors are mounted in an equally spaced manner with an open space formed between adjacent conductors;
a number of chips each forming, on the same surface, positive terminal and negative terminal, the chips being mounted to the surface of the substrate in a flip chip fashion with the positive and negative terminals thereof engaging corresponding ones of the conductors of the substrate to form electrical connection therebetween whereby opposite ends of each conductor form positive and negative electrodes for the chips connected thereto, ends of the conductors that are not engaged by the chips functioning as external terminals for connection with an external power source;
wherein the chips are selected to give off at least one color of light so that a single light emitting diode device selectively emits light of different colors, while possesses features of high voltage and small current and heat generated by the chips being effectively removed.
